(19) United States
(12) Patent Application Publication
(10) Pub. No.: US 2026/0045313 A1
(43) Pub. Date: Feb. 12, 2026

(54) NON-VOLATILE MEMORY DEVICE HAVING A FUSE TYPE MEMORY CELL ARRAY

(71) Applicant: SK keyfoundry Inc., Cheongju-si (KR)

(72) Inventors: Seongjun PARK, Suwon-si (KR); Inwoo HWANG, Cheongju-si (KR); Soyeon KIM, Seoul (KR); Sungbum PARK, Seongnam-si (KR); Yonghwan KIM, Cheongju-si (KR)

(73) Assignee: SK keyfoundry Inc., Cheongju-si (KR)

(21) Appl. No.: 19/174,685

(22) Filed: Apr. 9, 2025

(30) Foreign Application Priority Data
Aug. 9, 2024 (KR) 10-2024-0106628

(51) Int. Cl. G11C 17/18; G11C 17/16

(52) U.S. Cl. CPC G11C 17/18; G11C 17/16

(57) ABSTRACT

A non-volatile memory device based on a fuse type memory cell array includes an eFuse cell array including a plurality of unit cells in matrix form, each unit cell having a first switching element and an eFuse; an address decoder configured to activate, based on an address input from an external device, a word line used for program operation or read operation among a plurality of word lines; a current controller configured to supply a program current used for the program operation or a read current used for the read operation; a bit line sense amplifier configured to sense digital data output from the eFuse cell array and output the digital data; and a control logic configured to control the program operation or the read operation to be performed based on a control signal input from the external device.

### CROSS REFERENCE TO RELATED APPLICATION

The present application claims the benefit under 35 U.S. C. § 119(a) of Korean Patent Application No. 10-2024-0106628, filed on Aug. 9, 2024, in the Korean Intellectual Property Office, the entire disclosure of which is incorporated herein by reference for all purposes.

### BACKGROUND

### 1. Field

The present disclosure relates to a semiconductor non-volatile memory device having a fuse-type memory cell array.

### 2. Description of Related Art

Power ICs such as PMICs (power management ICs) require a non-volatile one-time-programmable (OTP) memory having a small capacity to perform an analog trimming function. OTP memory such as eFuses (electrical fuses) with a simple drive method and small footprint has been used as a small-capacity non-volatile OTP memory. Such an eFuse type OTP memory is programmed in such a manner as to blow the eFuse such that a resistance value of the eFuse is permanently changed to a value different from an initial resistance value before the blowing, by using an overcurrent of about 10 mA to 30 mA in a polysilicon fuse or a metal fuse.

Since the eFuse program requires overcurrent, the conventional eFuse has been implemented to differentiate paths of a current for the program operation and a current for the read operation from each other. However, the conventional eFuse implementation method has the problem of increasing the area of each unit cell, which may increase the overall size of the OTP memory device.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Various examples of the present disclosure relate to a non-volatile memory device including a fuse-type cell array having a small area, in particular, to a non-volatile memory device including a fuse-type cell array capable of reducing a quantity of components of a unit cell by steering the program current and the read current toward the same path to reduce an area of the unit cell.

In one general aspect, a non-volatile memory device based on a fuse type memory cell array, including: an eFuse cell array having a plurality of unit cells in matrix form, each unit cell having a first switching element and an eFuse; an address decoder configured to activate, based on an address input from an external device, a word line used for program operation or read operation among a plurality of word lines; a current controller configured to supply a program current used for the program operation or a read current used for the read operation; a bit line sense amplifier configured to sense digital data output from the eFuse cell array and output the digital data; and a control logic configured to control the program operation or the read operation to be performed based on a control signal input from the external device.

The eFuse cell array may be configured to form one row with a plurality of unit cells connected to each bit line of a plurality of bit lines; and to form one column with a plurality of unit cells connected to each word line of a plurality of word lines. Each unit cell may be connected to one bit line and one word line. Each unit cell may be configured to receive the program current or the read current through the one bit line and turn on or off the first switching element based on a signal input through the one word line.

The first switching element may be an NMOS transistor. The unit cell may have a structure in which the eFuse and the NMOS transistor may be connected in series between a bit line and a ground, and a word line among the plurality of word lines may be connected to a gate of the NMOS transistor, and a switching operation of the NMOS transistor may be controlled based on activation of the word line connected to the gate.

When the word line connected to the gate is activated to a high level, the NMOS transistor may be turned on to allow current to flow to the eFuse, and when the word line connected to the gate is deactivated to a low level, the NMOS transistor may be turned off to prevent current from flowing to the eFuse.

The first switching element may be a diode, and each unit cell may have a structure in which the eFuse and the diode are connected in series between a bit line and an inverted word line obtained by inverting a word line among the plurality of word lines, and a switching operation of the diode may be controlled by an activation of the inverted word line.

When the inverted word line is at a low level, the diode may be turned on to allow current to flow to the eFuse, and when the inverted word line is at a high level, the diode may be turned off to prevent current from flowing to the eFuse.

With respect to each bit line, the current controller may include a second switching element between a first power and the bit line to supply the program current, and may include a third switching element, a first resistor and a fourth switching element connected in series between a second power and the bit line to supply the read current.

A voltage of the second power may be less than or equal to a voltage of the first power.

When the program operation is performed, the second switching element may be configured to be turned on with respect to only one bit line among all bit lines, and turned off with respect to the remaining bit lines.

The third switching element may be a PMOS transistor, the fourth switching element may be an NMOS transistor configured to be turned on or off by a read activation signal, and the third switching element may be configured to be turned on/off by a signal obtained by inverting the read activation signal.

The bit line sense amplifier may include: a first sensing amplifier; and a dividing circuit configured to divide a voltage of a second power, the dividing circuit may include second and third resistors between the second power and the ground. The first sensing amplifier may be configured to output a high level (‘1’) when a first input is greater than a second input, and to output a low level (‘0’) when the first input is less than the second input. The first input may be a voltage at a point where the first resistor and the fourth switching element meet, and the second input may be a voltage at a point between the second resistor and the third resistor.

The first, second, and third resistors may have a same resistance value, and the resistance value of the first, second, and third resistors may be half of a sum of an initial resistance value before the eFuse is blown and a program resistance value after the eFuse is blown.

The bit line sense amplifier may further include a second sensing amplifier configured to amplify an output of the first sensing amplifier.

With respect to each bit line, the current controller may include a second switching element between a first power and the bit line to supply the program current, and a third switching element, a first resistor, and a fourth switching element connected in series between a second power and the bit line to supply the read current.

Each unit cell may be connected to one bit line and one word line. Further, each unit cell may be configured to receive the program current or the read current through the one bit line and turn on or off the first switching element based on a signal input through the one word line.

When the program operation is performed, the second switching element is configured to be turned on with respect to only one bit line among all bit lines, and turned off with respect to the remaining bit lines.

According to various examples of the present disclosure, a structure can proposed in which the program current and the read current flow identically within a unit cell, and the area in which the unit cell is formed can be reduced by reducing the quantity of the required components.

Other features and aspects will be apparent from the following detailed description, the drawings, and the claims.

### BRIEF DESCRIPTION OF THE DRAWINGS

FIG. 1 illustrates a block diagram of a non-volatile memory device having a conventional fuse-type cell array according to an example.

FIG. 2 illustrates a diagram illustrating a connection structure of a conventional unit cell in a non-volatile memory device having a fuse-type cell array according to an example.

FIG. 3 illustrates an exemplary diagram illustrating a flow of a read current and a write current of a conventional unit cell according to an example.

FIG. 4 illustrates a circuit diagram illustrating a structure of a unit cell proposed by the present disclosure.

FIG. 5 illustrates a block diagram of a non-volatile memory device having a fuse-type cell array proposed by the present disclosure.

FIG. 6 illustrates a circuit diagram illustrating a non-volatile memory device having a fuse-type cell array proposed by the present disclosure.

FIG. 7 illustrates a diagram illustrating a flow of a program current when a program operation is performed.

FIG. 8 illustrates a diagram illustrating a flow of a read current and an operation of a sensing logic when a read operation is performed.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The merits and characteristics of the present disclosure and a system, a device, and a method for achieving the merits and characteristics will become more apparent from the examples described in detail in conjunction with the accompanying drawings. However, the present disclosure is not limited to the disclosed examples, but may be implemented in various different ways. The examples are provided to only complete the disclosure of the present disclosure and to allow those skilled in the art to understand the category of the present disclosure. The present disclosure is defined by the category of the claims. The same reference numerals will be used to refer to the same or similar elements throughout the drawings.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. As used herein, the term “and/or” includes, but is not limited to any and all combinations of one or more of the associated listed items.

The terms used in the present specification are for describing example embodiments and are not intended to limit the inventive concept. In the present specification, a singular form also includes a plural form unless particularly stated in the phrase. Components, steps, operations and/or elements that are referred to by terms “comprises” and/or “comprising” used in the inventive concept do not exclude presence or addition of one or more other components, steps, operations and/or elements.

Although the terms “first”, “second”, and the like are used for describing various components, these components are not confined by these terms. These terms are merely used for distinguishing one component from the other components.

Therefore, a first component to be mentioned below may be a second component in a technical concept of the present disclosure. Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the related art and will not be interpreted in an idealized or overly formal sense unless expressly so defined herein.

A term “part” or “module” used in the examples may mean software components or hardware components such as a field programmable gate array (FPGA), an application specific integrated circuit (ASIC). The “part” or “module” performs certain functions. However, the “part” or “module” is not meant to be limited to software or hardware. The “part” or “module” may be configured to be placed in an addressable storage medium or to restore one or more processors. Thus, for one example, the “part” or “module” may include components such as software components, object-oriented software components, class components, and task components, and may include processes, functions, attributes, procedures, subroutines, segments of a program code, an drivers, firmware, microcode, circuits, data, databases, data structures, tables, arrays, and variables. Components and functions provided in the “part” or “module” may be combined with a smaller number of components and “parts” or “modules” or may be further divided into additional components and “parts”or “modules”.

Methods or algorithm steps described relative to some examples of the present invention may be directly implemented by hardware and software modules that are executed by a processor or may be directly implemented by a combination thereof. The software module may be resident on a RAM, a flash memory, a ROM, an EPROM, an EEPROM, a resistor, a hard disk, a removable disk, a CD-ROM, or any other type of record medium known to those skilled in the art. An exemplary record medium is coupled to a processor and the processor can read information from the record medium and can record the information in a storage medium. In another way, the record medium may be integrally formed with the processor. The processor and the storage medium may reside in an application specific integrated circuit (ASIC). The ASIC may be resident within a user's terminal.

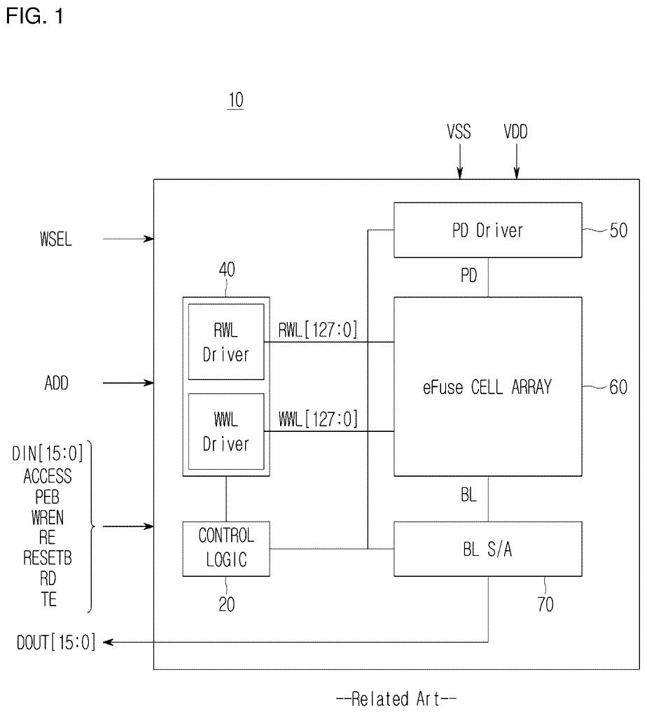

FIG. 1 illustrates a block diagram of a non-volatile memory device having a conventional fuse-type cell array according to an example. In various examples, the fuse means an electrical fuse (eFuse) and the non-volatile memory device having a fuse-type cell array may mean a one-time programmable memory in an eFuse method. The eFuse method may mean a method for programming binary information by blowing a fuse through application of a high voltage to a fuse of each unit cell or maintaining the fuse as it is. Depending on whether the fuse is blown or not blown, the resistance varies and based on a resistance value sensed when the read operation is performed, information of 0 or 1 may be obtained. Referring to FIG. 1, the non-volatile memory device 10 may include a control logic 20, a word line driver 40, a programing driver 50, an eFuse cell array 60, and a bit line sense amplifier (BL S/A) 70.

The control logic 20 is configured to generate an internal control signal suitable for a program operation or a read operation based on an external control signal input through an input terminal, and to supply the generated control signal to the word line driver 40, the programing driver 50, and the bit line sense amplifier 70. The input terminal may include, for example, a DIN[15:0] terminal, an ACCESS terminal, a PEB terminal, a WREN terminal, an RE terminal, an RESETB terminal, an RD terminal, and a TE terminal.

The word line driver 40 includes a write word line driver, a read word line driver, and a word line selector, and may activate a write word line (WWL) used in the program operation, or a read word line (RWL) used in the read operation. For example, the word line driver 40 may select and activate a certain write word line (WWL) or a read word line (RWL) based on an address signal and control signals ACCESS, WREN, and RD input through an ADD terminal.

The programing driver 50 includes a bit line selector, and may supply a program current to a common node of a column which corresponds to a certain bit line based on a signal input through a WSEL terminal.

The eFuse cell array 60 may include a plurality of unit cells. The plurality of unit cells may be connected to a plurality of word lines and a plurality of bit lines. Each of the plurality of unit cells may perform a data write operation based on a program current provided from the programming driver 50. Among the plurality of unit cells forming the eFuse cell array 60, the unit cells connected to the same bit line and/or having the same common node may be referred to as a column. In addition, among the plurality of unit cells forming the eFuse cell array 60, the unit cells connected to the same word line may be the unit cells connected to one row.

The bit line sense amplifier 70 may sense digital data output from a bit line connected to the eFuse cell array 60, and output the sensed digital data through an output terminal DOUT.

In FIG. 1, a VDD terminal and a VSS terminal may be terminals configured to supply an external supply power and a ground voltage, and the VDD terminal may include a first VDD (VDD1) for the program operation and a second VDD (VDD2) for the read operation.

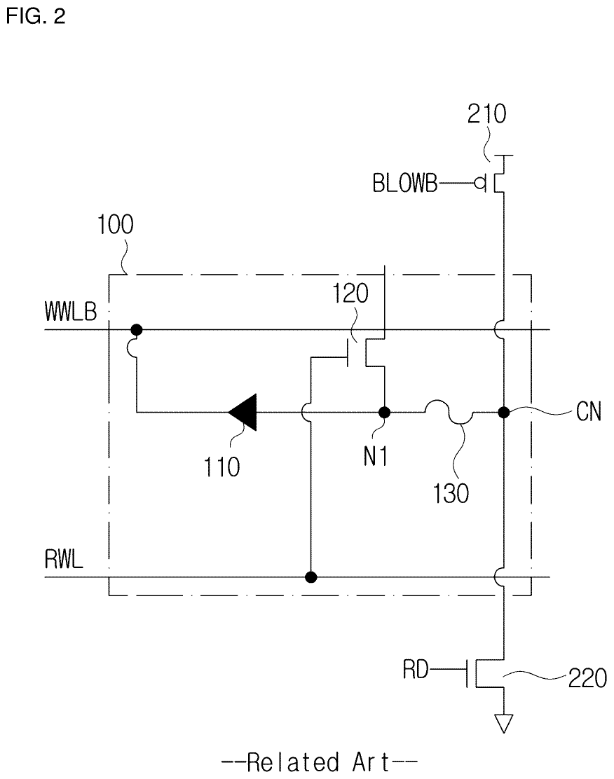

FIG. 2 illustrates a diagram illustrating a connection structure of a conventional unit cell in the non-volatile memory device having the fuse-type cell array according to an example.

Referring to FIG. 2, the unit cell 100 may include a diode 110, a first NMOS transistor (or a first switching element) 120, and a fuse 130.

The diode 110 may be connected between a WWLB and a first node N1. The WWLB may be a line into which an inverted signal WWLB is input with respect to a WWL signal representing whether a write word line is activated. For example, an anode of the diode 110 may be connected to the fuse 130 through the first node N1, and a cathode of the diode 110 may be connected to the WWLB.

A gate of the first NMOS transistor 120 may be connected to an RWL, and a source and a drain thereof may be connected to the bit line and the first node N1. For example, the drain of the first NMOS transistor 120 may be connected to the bit line, and the source thereof may be connected to the fuse 130 through the first node N1. The RWL may be a line into which the RWL signal, which represents whether the read word line is activated, is input.

The fuse 130 may be connected between the first node N1 and a common node CN. The common node CN exists per each row of the eFuse cell array 60, and the unit cells disposed in each row may be connected to one common node CN. The fuse 130 may use a structure in which a silicide such as CoSi2 is formed on a poly-silicon (Poly-Si) layer. The fuse 130 may be supplied with a program current through the common node CN. Here, the common node CN may be referred to as a common line CL. The common line CL or the common node CN may be used in the read operation as well as the program operation. It may be referred to as the common node CN or the common line CL to mean that the common line CL or the common node CN is commonly used in the program operation and the read operation.

According to an example, the fuse 130 of the unit cell 100 may be connected to a second NMOS transistor (or a second switching element) 220 disposed outside the unit cell through the common node CN, and a first PMOS transistor (or a third switching element) 210. Here, the second and third switching elements 220 and 210 may be disposed outside the unit cell 100. This is because the second and the third switching elements 220 and 210 are connected in common to the plurality of unit cells, which are included in the same row. For example, the second NMOS transistor 220 and the first PMOS transistor 210 may be connected to the plurality of unit cells, which are included in an n-th row, through the common node CN.

As described above, the second and third switching elements 220 and 210 may minimize the size of each unit cell 100, and reduce the overall size of the eFuse cell array 60 formed by the plurality of unit cells by disposing the second and third switching elements 220 and 210 outside the unit cell. That is, by reducing a size of the eFuse cell array 60 occupying the greatest area among the areas of chips of the non-volatile memory device 10, there is an effect of reducing a size of a chip.

A gate terminal of the second NMOS transistor 220 may be connected to the RD, and ends of the source and the drain may be connected to the common node CN and the ground. For example, the second NMOS transistor 220 may be connected to fuse cells of the plurality of unit cells through the common node CN. The RD line may be a line to which a read activation signal is supplied.

The gate terminal of the first PMOS transistor 210 may be connected to a BLOWB line, and ends of the source and drain may be connected to a power supply voltage and the common node CN. For example, the first PMOS transistor 210 may be connected to fuses of the plurality of unit cells through the common node CN. The BLOWB line may be a line to which an inverted signal with respect to a signal BLOW representing whether to perform fuse blowing is supplied.

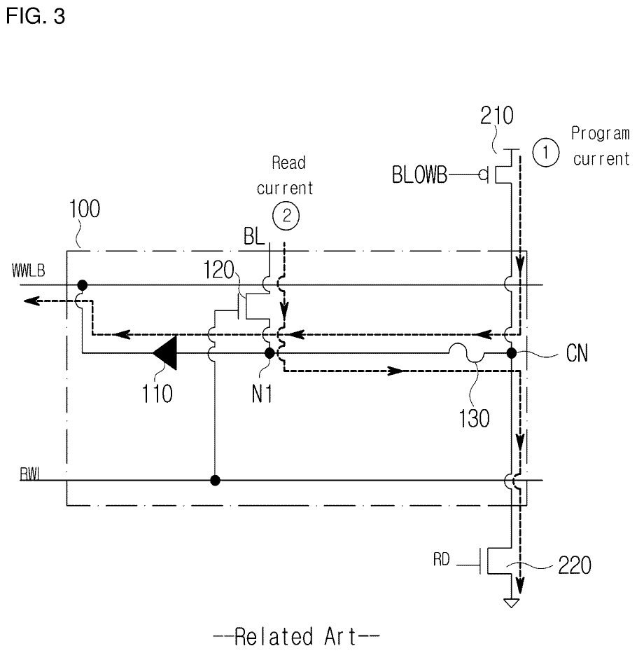

FIG. 3 illustrates schematically the flow of a read current and a write current of a conventional unit cell according to an example.

Referring to FIG. 3, an arrow \textcircled{1} in a dotted line shows the flow of current to the unit cell 100 when the program operation is performed.

According to the example, the first PMOS transistor 210 may be turned off when a signal of a high level is provided thereto through the BLOWB line. Here, the BLOWB of a high level may show that fuse blowing is not needed.

According to the example, the first PMOS transistor 210 may provide a program current according to a program voltage to the common node CN, when a signal of a low level is provided thereto through the BLOWB line. Here, the BLOWB of a low level may show that the fuse blowing is needed for programming of data ‘1’. The program current is delivered to the fuse 130 through the common node CN, and the fuse 130 may be programmed or blown by the program current. The programing or blowing means an operation to increase a resistance of the fuse. The program current flows from the anode to the cathode of the fuse 130, and may evade toward the WWLB through the diode 110. The WWLB of the word line subjected to be programmed may be at a low level (‘0’), and the WWLB of the other word line may be at a high level (‘1’). When the WWLB is at a high level, a forward voltage is not applied to the PN diode 110 and a current for the program operation does not flow. When the WWLB is at a low level, the forward voltage is applied to the PN diode and the current for the program operation may flow.

Referring to FIG. 3, an arrow \textcircled{2} in a dotted line shows a path of a current flow with respect to the unit cell 100 when the read operation is performed.

According to the example, the first NMOS transistor 120 may be turned off when a signal of a low level is provided to the gate through the RWL line, and may be turned on when a signal of a high level is provided to the gate through the RWL line. Here, the RWL signal of a low level may represent that the corresponding read word line is not selected, and the RWL signal of a high level may represent that the corresponding read word line is selected.

According to the example, the second NMOS transistor 220 may be turned off when a signal of a low level is provided to the gate through the RD line, and may be turned on when a signal of a high level is provided to the gate through the RD line. Here, the RD of a high level may represent a read mode in which a read operation should be performed, and the RD of a low level may represent that it is not a read mode.

According to the example, when the first NMOS transistor 120 and the second NMOS transistor 220 are both turned on, the first NMOS transistor 120 may apply a read current to the fuse 130 according to a read voltage provided from the bit line BL. The read current may pass through the fuse 130, and a value of the read current may vary according to a resistance of the fuse 130. For example, a value of the read current in case the fuse 130 is blown may be smaller than a value of the read current in case the fuse 130 is not blown. The read current which has passed through the fuse 130 may flow to the second NMOS transistor 220 through the common node CN. Here, the read current flows in a direction from the cathode to the anode of the fuse 130, and therefore, a direction of the read current may seem to flow in a direction opposite to a direction of the program current. In addition, the read current does not pass through the diode 110, and thus, a high driving voltage need not be used for the read operation. Therefore, the read current may use a low driving current. A value of the read operation may be used for checking whether the fuse 130 is programmed.

Referring to FIGS. 2 and 3, the conventional unit cell 100 may include the first NMOS transistor (or the first switching element) 120 used for the read operation, and the diode 110 used for the program operation, as well as the fuse 130. If a flow of the current when the read operation is performed and a flow of the current when the program operation is performed are identical, it is possible to reduce a size of each unit cell 100 by reducing one necessary component, and to reduce the entire size of the eFuse cell array 60 formed with the plurality of unit cells. That is, by reducing a size of the eFuse cell array 60 which occupies the greatest area of the areas of chips of the non-volatile memory device 10, it is possible to reduce a size of a chip.

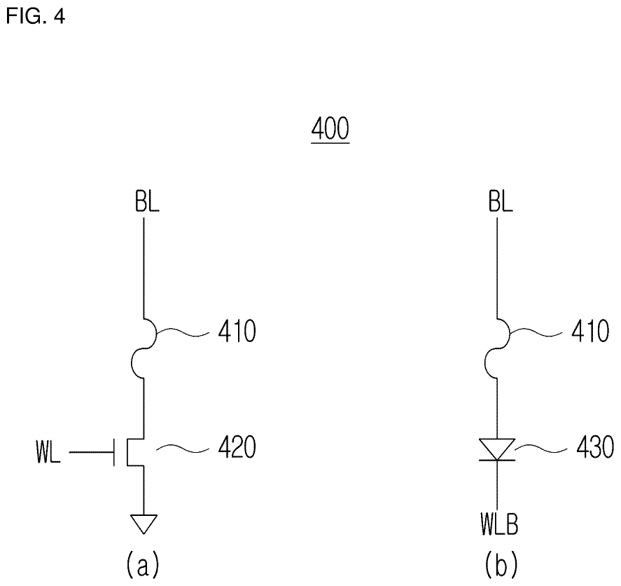

FIG. 4 illustrates a circuit diagram illustrating a structure of the unit cell proposed by the present disclosure.

Referring to FIG. 4, the unit cell 400 proposed by the present disclosure may be configured with an eFuse 410 and an NMOS transistor 420, or configured with the eFuse 410 and a diode 430, as illustrated in FIG. 4(a) and FIG. 4(b). Here, the NMOS transistor 420 and the diode 430 may serve as the switching elements, and may allow current to flow to the eFuse 410 or prevent current from flowing to the eFuse 410. At this time, unlike what is illustrated in FIG. 3, both the program current and the read current may be applied through the bit line BL and pass through the eFuse 410 and the NMOS transistor 420, or pass through the eFuse 410 and the diode.

In addition, when compared with a cell structure of the conventional unit cell, the unit cell 400 proposed by the present disclosure uses only two components, therefore a size of each unit cell 400 can be reduced, and the entire size of the eFuse cell array 60 formed with the plurality of unit cells may be reduced. That is; by reducing a size of the eFuse cell array 60 occupying the greatest area among the areas of chips of the non-volatile memory device 10, it is possible to reduce a size of a chip.

Referring to FIG. 4(a), in case where the eFuse 410 and the NMOS transistor 420 are used in the unit cell 400, when the word line WL is at a high level, the NMOS transistor 420 is turned on and the current flows, and when the word line WL is at a low level, the NMOS transistor 420 is turned off and the current does not flow.

Referring to FIG. 4(b), in case where the eFuse 410 and the diode 430 are used in the unit cell 400, when an inverted word line WLB obtained by inverting a word line WL signal is at a low level, a forward voltage is applied to the diode 430 and the current flows, and when the inverted word line WLB is at a high level, a reverse voltage is applied to the diode 430 and the current does not flow. Here, the WLB is a signal obtained by inverting a word line WL.

The WL or the WLB are signals used in common when the program operation or the read operation is performed, and there is a difference that according to the conventional implementation, the WWL is used when the program operation is performed, and each different signal line of the RWL is used when the read operation is performed.

There may be a difference in the current applied through the BL line between the current when the program operation is performed and the current when the read operation is performed, and a circuit which controls supply of the program current and the read current may be disposed outside the unit cell.

According to the example, in order to additionally reduce a size of the unit cell, a width of the NMOS transistor 420 may be reduced. In order to improve the sensing performance, a two-stage sense amplifier may be used.

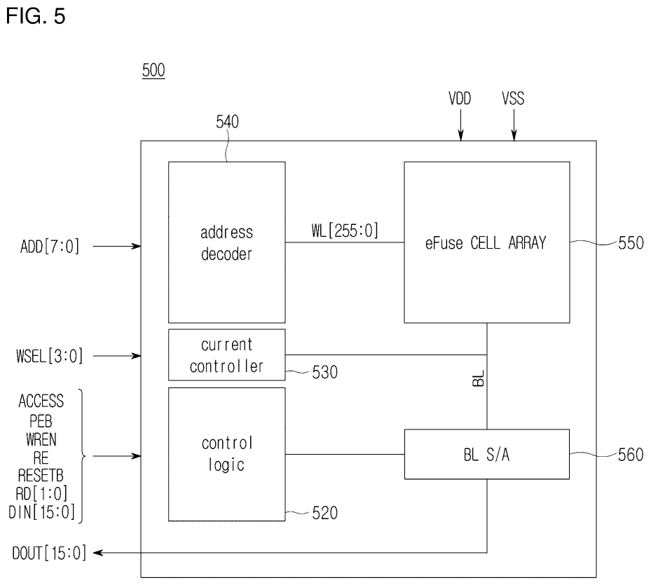

FIG. 5 illustrates a block diagram of a non-volatile memory device having a fuse-type cell array proposed by the present disclosure.

Referring to FIG. 5, a non-volatile memory device 500 includes a control logic 520, an address decoder 540, an eFuse cell array 550, a bit line sense amplifier (BL S/A) 560, and a current controller 530.

The control logic 520 is configured to generate an internal control signal suitable for the program operation or the read operation based on an external control signal input through an input terminal, and to supply the generated control signal to the address decoder 540, the current controller 530, and the bit line sense amplifier 560. The input terminal may include, for example, a DIN[15:0] terminal, an ACCESS terminal, a PEB terminal, a WREN terminal, an RE terminal, an RESETB terminal, and an RD terminal.

The address decoder 540 may activate a word line WL used for the program operation or a word line WL used for the read operation by decoding an address ADD input thereto. For example, the address decoder 540 may select and activate a word line WL for the program operation or a word line WL for the read operation based on an address signal and control signals ACCESS, WREN, and RD input through an ADD terminal. In this case, a word line WL for the program operation and a word line WL for the read operation are not separately present, and may be present as one.

The current controller 530 includes a bit line selector, and may determine whether falling within a program mode or a read mode based on the control signals ACCESS, WREN, and RD or a signal received from the control logic 520, and when falling within the program mode, the current controller 530 may supply a program current to a common node of a column which corresponds to a certain bit line based on a signal input through a WSEL terminal. In addition, when falling within the read mode, the current controller 530 may supply a read current to a common node of a column which corresponds to a certain bit line.

The eFuse cell array 550 may include a plurality of unit cells. The plurality of unit cells may be connected to a plurality of word lines and a plurality of bit lines. Each of the plurality of unit cells may perform a program operation based on a program current applied through a bit line. Among the plurality of unit cells forming the eFuse cell array 550, the unit cells connected to the same bit line and/or having the same common node may be referred to as a column. In addition, among the plurality of unit cells forming the eFuse cell array 550, the unit cells connected to the same word line may be the unit cells connected to one row.

The bit line sense amplifier 560 may sense digital data output from a bit line connected to the eFuse cell array 550, and output the sensed digital data through an output terminal DOUT.

In FIG. 5, a VDD terminal and a VSS terminal may be terminals configured to supply an external supply power and a ground voltage. The VDD terminal may include a first VDD (VDD1) for the program operation and a second VDD (VDD2) for the read operation. According to the example, the first VDD (VDD1) may be a voltage between 5.5V and 6V, and the second VDD (VDD2) may be a voltage between 1.6V and 5.5V.

When comparing FIG. 1 which is a block diagram of the conventional non-volatile memory device and FIG. 5 which is a block diagram of the non-volatile memory device proposed by the present disclosure, with respect to performing a read operation based on an address ADD, or selecting a word line for a program operation, the conventional device includes each separate WRL driver and WWL driver, and generates a word line RWL for a read operation and a word line WWL for a program operation separately, while the device proposed by the present disclosure may generate only one word line WL which can be used for both the read operation and the program operation based on an address ADD. Therefore, the non-volatile memory device proposed by the present disclosure may reduce a size of a logic configured to decode an address ADD compared to the conventional non-volatile memory device.

In addition, the conventional non-volatile memory device provides a current needed for a program operation and a current needed for a read operation through separate blocks, that are, the programing driver 50 and the bit line sense amplifier 70, and supplies the currents to each of a PD line and a BL line separately. However, the non-volatile memory device proposed by the present disclosure is configured to generate the program current or the read current in the current controller 530 and to supply the current to the BL line.

Further, when comparing FIG. 4 showing a structure of the unit cell proposed by the present disclosure and FIG. 2 showing a structure of the conventional unit cell, the structure of the unit cell proposed by the present disclosure uses only two components, which means, the structure thereof uses one less component than the structure of the conventional unit cell, thereby reducing a size of an area occupied by the unit cell and a size of the non-volatile memory device. For example, a cell area according to the structure of the conventional unit cell is 36 μm² or so, and a cell area according to the structure of the unit cell proposed by the present disclosure is 24 μm² or so. A size of a final non-volatile memory device generated by adding up blocks illustrated in FIG. 1 or FIG. 5 is 0.22 mm² or so according to the conventional method, and a size thereof is 0.14 mm² or so according to the method proposed by the present disclosure, therefore, the size can be reduced.

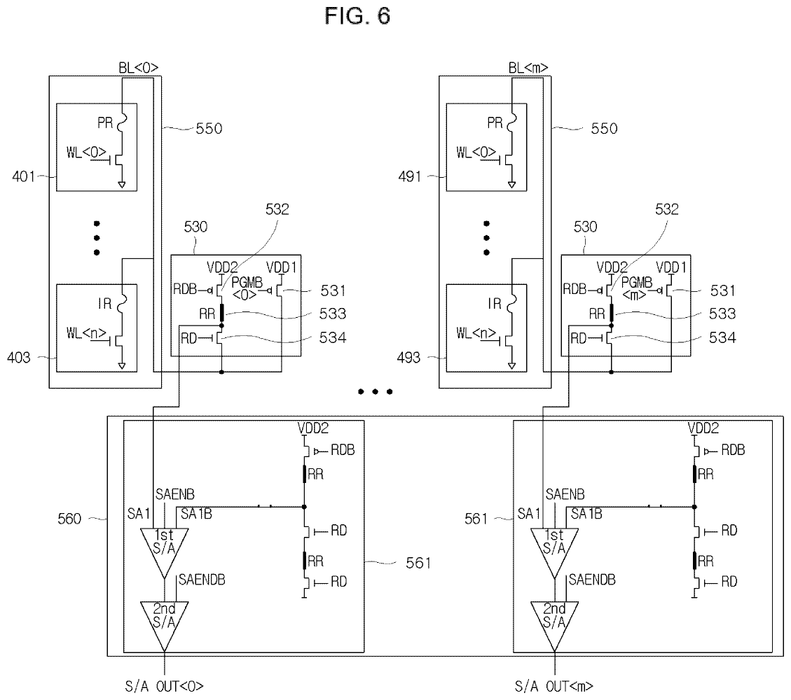

FIG. 6 illustrates a circuit diagram illustrating a non-volatile memory device having a fuse-type cell array proposed by the present disclosure.

Referring to FIG. 6, the eFuse cell array 550 may include a plurality of unit cells. The plurality of unit cells may be connected to n+1 word lines and m+1 bit lines. Among the plurality of unit cells forming the eFuse cell array 550, the unit cells connected to the same bit line and/or having the same common node may be referred to as a column. In addition, among the plurality of unit cells forming the eFuse cell array 550, the unit cells connected to the same word line may be the unit cells connected to one row. For example, the unit cells 401 and 403 may be referred to as unit cells of a first row, and the unit cells 491 and 493 may be referred to as unit cells of a m+1th row. In addition, the unit cells 401 and 491 may be referred to as unit cells of a first column and the unit cells 403 and 493 may be referred to as unit cells of a n+1th column.

The current controller 530 may include a logic capable of providing a program current and a logic capable of providing a read current for each of rows.

Referring to FIG. 6, the logic capable of providing a program current may be configured with one PMOS transistor 531 connecting between the bit line BL and the power supply VDD1. The PMOS transistor 531 may be referred to as a switching element, and when the PGMB signal connected to a gate is a low level, the PMOS transistor 531 may connect the power supply VDD1 to the bit line BL to provide the program current (e.g., between 7.4 mA and 11.8 mA), and when the PGMB signal connected to a gate is a high level, the PMOS transistor 531 may disconnect the power supply VDD1 and the bit line BL and may not provide the program current. Here, the PGMB signal may be provided for each of bit lines, and values of the PGMB signal may be each different. According to the example, when a signal configured to activate a program (e.g.: WREN) among external control input signals is activated, the PGMB signal per bit line may be generated based on a data input signal (e.g.: DIN[15:0]). That is, a PGMB[n] signal with respect to an n-th bit line becomes 0 when the WREN is 1 and DIN[n] is 1, and may turn on the PMOS transistor 531 and programming a unit cell connected to an activated word line among the unit cells connected to a corresponding bit line BL can be done. If the WREN is 0 and DIN[n] is 0, the PGMB[n] may be 1. That is, the PGMB[n] signal may be determined by a NAND logic having the WREN and DIN[n] as input.

According to another example, in case of the eFuse OTP non-volatile memory device, a bit which can be programmed at a time may be 1 bit, and therefore, only a signal of 1 bit among data input signals (e.g.: DIN[15:0]) is 1, and signals of the rest may be 0.

Referring to FIG. 6, the logic capable of providing a read current may be configured by series-connecting one PMOS transistor 532, one resistor 533, and one NMOS transistor 534 between the bit line BL and the power supply VDD2. The PMOS transistor 532 may be turned on when the RDB signal applied to the gate is 0, and the NMOS transistor 534 may be turned on when the RD signal applied to the gate is 1, and may provide a read current to the bit line BL. At this instance, the RDB signal and the RD signal may be applied to all the bit lines in the same way. That is, in case of a program operation, a program operation of 1 bit at a time is possible, however, in case of a read operation, a read operation with respect to all bit lines may be simultaneously possible.

The bit line sense amplifier 560 may include a sensing logic 561 capable of sensing a resistance of each unit cell per bit line. Referring to FIG. 6, the sensing logic 561 may be configured with a voltage divider and two sensing amplifiers (S/A). The sensing logic 561 may compare a voltage of the voltage divider and a voltage provided by the unit cell and output a signal of a low level or a high level (S/A OUT) corresponding to 0 or 1.

Referring to FIG. 6, a shape, or a capacity of the eFuse cell array 550 is not specifically limited. That is, a capacity of the eFuse cell array 550 may be determined by a size of m or n. For example, when n is 127 and m is 15, a capacity of the eFuse cell array 550 may be calculated to be 2048 bit by an equation, 128 rows*16 columns=2048. That is, the eFuse cell array 550 may store data of 2048 bit. The eFuse cell array 550 may be connected to 128 word lines and 16 bit lines. Therefore, the eFuse cell array 550 may include 2048 unit cells in total.

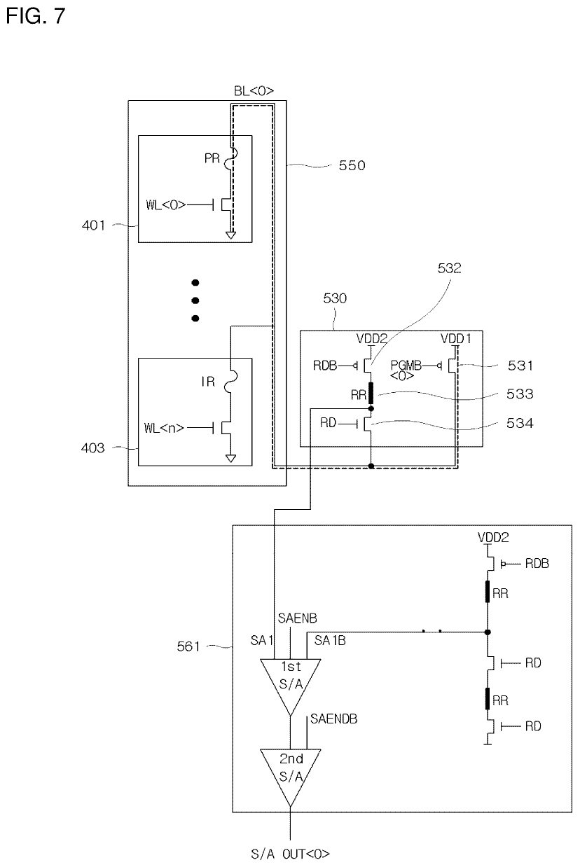

FIG. 7 illustrates a diagram illustrating a flow of a program current when a program operation is performed. FIG. 7 illustrates an example of programming the unit cells connected to one bit line, for convenience of description.

Referring to FIG. 7, when the program operation with respect to a corresponding column is performed by the control signals (ACCESS, WREN, and RD) from an external device, the RD is at a low level, the RDB which is an inverted signal of the RD is at a high level, and the PGMB is at a low level, thereby the PMOS transistor 531 is turned on, and the power supply VDD1 voltage may be applied to each of the unit cells 401 and 403 connected to the corresponding column. Among them, as illustrated in FIG. 7, in the unit cell 401 whose word line is at a high level, the corresponding PMOS transistor is turned on and the current flow through the fuse, and in the unit cell 430 whose word line is at a low level, the corresponding PMOS transistor is turned off and the current may not flow through the fuse. Therefore, by providing only a word line, desired to be programed in the corresponding bit line, with an ON signal while the program operation is performed, only the unit cell desired to be programmed can be programmed. The fuse of the programmed unit cell is blown, and may have a resistance value (Programmed R, PR) that is different from an initial resistance value (Initial R, IR) before the blowing.

In addition, by performing the above-described operation for each of the bit lines, the program operation for all the unit cells may be completed.

It is possible to program the unit cells connected to one word line in a different manner from what is illustrated in FIG. 7. For example, it is possible to blow the fuse of the desired unit cell only, by turning on the word line 0 (WL<0>) only and turning off the rest of the word lines, turning on the PMOS transistor 531 by making the PGMB of the bit line connected to the unit cell desired to blow the fuse in the corresponding word line be at a low level, and turning off the PMOS transistor 531 by making the PGMB of the bit line connected to the unit cell desired to maintain the fuse as it is be at a high level. At this instance, according to the example, the bit blowable at a program operation may be 1 bit. That is, the program operation may be performed in only one unit cell at a time. By performing the above-described operation for each of the unit cells requiring the operation, the program operation for all the unit cells may be completed.

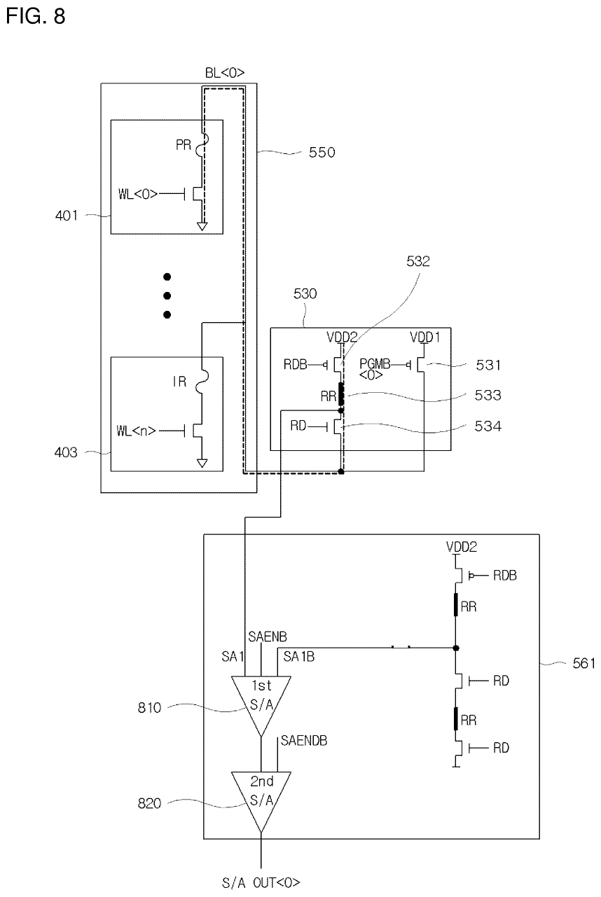

FIG. 8 illustrates a diagram illustrating a flow of a read current and an operation of the sensing logic when a read operation is performed.

FIG. 8 illustrates a read operation for one unit cell for convenience of description. However, referring to FIG. 8, it is possible to read programmed values in all the unit cells connected to one word line of all the bit lines, at a time.

Referring to FIG. 8, when a read operation is performed by the control signals ACCESS, WREN, and RD from the external device, the RD is at a high level, the RDB which is an inverted signal of the RD is at a low level, and the PGMB is at a high level, thereby the PMOS transistor 532 and the NMOS transistor 534 are turned on, and a voltage of the power supply VDD2 may be applied to each of the unit cells 401 and 403 connected to the corresponding row. Among them, as illustrated in FIG. 8, in the unit cell 401 whose word line is at a high level, the corresponding PMOS transistor is turned on and a current flows through the fuse and evades toward the ground (VSS or the ground), and in the unit cell 403 whose word line is at a low level, the corresponding PMOS transistor is turned off and the current may not flow.

In the illustrated example in FIG. 8, a voltage V_{SA1} input into an SA terminal of the first sensing amplifier 810 may be a voltage dividing the VDD2 into a reference resistance (Reference R, RR) and a programmed resistance (Programmed R, PR). That is, the voltage may be calculated by an equation, V_{SA1}=(VDD2*PR)/(PR+RR).

Meanwhile, when an n-th word line (WL<n>) is at a high level, and the rest of the word lines are at a low level, the current flows only through the fuse of the unit cell 403. Then, a voltage V_{SA1} input into the SA terminal of the first sensing amplifier 810 may be a voltage dividing the VDD2 into a reference resistance RR and an initial resistance IR. That is, the voltage may be calculated by an equation, V_{SA1}=(VDD2*IR)/(IR+RR).

In addition, referring to FIG. 8, a voltage V_{SAB} input into an SAB terminal of the first sensing amplifier 810 when a read operation is performed may be a voltage which divides the VDD2 voltage into two reference resistances RR. Therefore, the voltage may be calculated by an equation, V_{SAB}=VDD2*RR/(RR+RR)=VDD2/2.

According to the example, the initial resistance IR may be 600 ohm, the programmed resistance PR may be 1500 ohm, and the reference resistance RR may be 1050 ohm which is determined by an equation, RR=(IR+PR)/2.

Then, in case of the unit cell in which the fuse is not blown, a voltage of 0.363 VDD2 is applied to the SA terminal of the first sensing amplifier 810. In addition, a voltage of 0.5 VDD2 is applied to the SAB terminal, and thus, an output of the first sensing amplifier 810 becomes 0, and after being amplified in the second sensing amplifier 820, a signal of a low level may be output.

In case of the unit cell whose fuse is blown, a voltage of 0.588 VDD2 is applied to the SA terminal of the first sensing amplifier 810. In addition, a voltage of 0.5 VDD2 is applied to the SAB terminal, and thus, an output of the first sensing amplifier 810 becomes 1, and after being amplified in the second sensing amplifier 820, a signal of a high level may be output.

As described above, even if configuring a structure of the unit cell with the fuse and the PMOS transistor only, the size of the non-volatile memory device may be reduced while performing the same function as that of the conventional implementation.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A non-volatile memory device based on a fuse type memory cell array, comprising:
an eFuse cell array comprising a plurality of unit cells in matrix form, each unit cell having a first switching element and an eFuse;
an address decoder configured to activate, based on an address input from an external device, a word line used for program operation or read operation among a plurality of word lines;
a current controller configured to supply a program current used for the program operation or a read current used for the read operation;
a bit line sense amplifier configured to sense digital data output from the eFuse cell array and output the digital data; and
a control logic configured to control the program operation or the read operation to be performed based on a control signal input from the external device.

2. The non-volatile memory device of claim 1, wherein the eFuse cell array is configured to form one row with a plurality of unit cells connected to each bit line of a plurality of bit lines; and to form one column with a plurality of unit cells connected to each word line of a plurality of word lines,
wherein each unit cell is connected to one bit line and one word line, and
wherein each unit cell is configured to receive the program current or the read current through the one bit line and turn on or off the first switching element based on a signal input through the one word line.

3. The non-volatile memory device of claim 2, wherein the first switching element is an NMOS transistor,
wherein each unit cell has a structure in which the eFuse and the NMOS transistor are connected in series between a bit line and a ground, and
wherein a word line among the plurality of word lines is connected to a gate of the NMOS transistor, and a switching operation of the NMOS transistor is controlled based on activation of the word line connected to the gate.

4. The non-volatile memory device of claim 3, wherein when the word line connected to the gate is activated to a high level, the NMOS transistor is turned on to allow current to flow to the eFuse, and
wherein when the word line connected to the gate is deactivated to a low level, the NMOS transistor is turned off to prevent current from flowing to the eFuse.

5. The non-volatile memory device of claim 1, wherein the first switching element is a diode,
wherein each unit cell has a structure in which the eFuse and the diode are connected in series between a bit line and an inverted word line obtained by inverting a word line among the plurality of word lines, and
wherein a switching operation of the diode is controlled by an activation of the inverted word line.

6. The non-volatile memory device of claim 5, wherein when the inverted word line is at a low level, the diode is turned on to allow current to flow to the eFuse, and
wherein when the inverted word line is at a high level, the diode is turned off to prevent current from flowing to the eFuse.

7. The non-volatile memory device of claim 3, wherein with respect to each bit line, the current controller comprises:
a second switching element between a first power and the bit line to supply the program current, and
a third switching element, a first resistor and a fourth switching element connected in series between a second power and the bit line to supply the read current.

8. The non-volatile memory device of claim 7, wherein a voltage of the second power is less than or equal to a voltage of the first power.

9. The non-volatile memory device of claim 7, wherein, when the program operation is performed, the second switching element is configured to be turned on with respect to only one bit line among all bit lines, and turned off with respect to the remaining bit lines.

10. The non-volatile memory device of claim 7, wherein the third switching element is a PMOS transistor,
wherein the fourth switching element is an NMOS transistor configured to be turned on or off by a read activation signal, and
wherein the third switching element is configured to be turned on or off by a signal obtained by inverting the read activation signal.

11. The non-volatile memory device of claim 10, wherein the bit line sense amplifier comprises:
a first sensing amplifier; and
a dividing circuit configured to divide a voltage of the second power,
wherein the dividing circuit comprises second and third resistors between the second power and the ground,
wherein the first sensing amplifier is configured to output a high level (‘1’) when a first input is greater than a second input, and to output a low level (‘0’) when the first input is less than the second input,
wherein the first input is a voltage at a point where the first resistor and the fourth switching element meet, and
wherein the second input is a voltage at a point between the second resistor and the third resistor.

12. The non-volatile memory device of claim 11, wherein the first, second, and third resistors have a same resistance value, and
wherein the resistance value of the first, second, and third resistors is half of a sum of an initial resistance value before the eFuse is blown and a program resistance value after the eFuse is blown.

13. The non-volatile memory device of claim 10, wherein the bit line sense amplifier further comprises a second sensing amplifier configured to amplify an output of the first sensing amplifier.

14. The non-volatile memory device of claim 5, wherein with respect to each bit line, the current controller comprises:
a second switching element between a first power and the bit line to supply the program current, and
a third switching element, a first resistor, and a fourth switching element connected in series between a second power and the bit line to supply the read current.

15. A non-volatile memory device, comprising:
an eFuse cell array comprising unit cells arranged in a matrix, each unit cell comprising a first switching element and an eFuse connected to a bit line;
an address decoder configured to activate a word line used for program operation or read operation among a plurality of word lines, based on an address input from an external device;
a current controller configured to supply a program current used for the program operation or a read current used for the read operation to the bit line, wherein the current controller comprises:
a second switching element between a first power and the bit line to supply the program current, and
a third switching element, a first resistor, and a fourth switching element connected in series between a second power and the bit line to supply the read current;
a bit line sense amplifier configured to sense digital data output from the eFuse cell array and output the digital data; and
a control logic configured to control the program operation or the read operation to be performed based on a control signal input from the external device.

16. The non-volatile memory device of claim 15, wherein the first switching element is an NMOS transistor,
wherein each unit cell has a structure in which the eFuse and the NMOS transistor are connected in series between the bit line and a ground, and
wherein a word line among the plurality of word lines is connected to a gate of the NMOS transistor, and a switching operation of the NMOS transistor is controlled by an activation of the word line connected to the gate.

17. The non-volatile memory device of claim 16, wherein when the word line connected to the gate of the NMOS transistor is activated to a high level, the NMOS transistor is turned on to allow current to flow to the eFuse, and
wherein when the word line connected to the gate of the NMOS transistor is deactivated to a low level, the NMOS transistor is turned off to prevent current from flowing to the eFuse.

18. The non-volatile memory device of claim 15, wherein the first switching element is a diode,
wherein each unit cell has a structure in which the eFuse and the diode are connected in series between the bit line and an inverted word line obtained by inverting a word line among the plurality of word lines, and
wherein a switching operation of the diode is controlled by an activation of the inverted word line connected to the diode.

19. The non-volatile memory device of claim 15, wherein each unit cell is connected to one bit line and one word line, and
wherein each unit cell is configured to receive the program current or the read current through the one bit line and turn on or off the first switching element based on a signal input through the one word line.

20. The non-volatile memory device of claim 15, wherein, when the program operation is performed, the second switching element is configured to be turned on with respect to only one bit line among all bit lines, and turned off with respect to the remaining bit lines.
